(19) United States
(12) Patent Application Publication
(10) Pub. No.: US 2026/0181943 A1
(43) Pub. Date: Jun. 25, 2026

(54) CELL REGION WITH ACTIVE REGIONS HAVING CONCAVE POLYGON SHAPES AND METHOD OF MANUFACTURING SAME

(71) Applicant: TAIWAN SEMICONDUCTOR MANUFACTURING COMPANY, LTD., Hsinchu (TW)

(72) Inventors: Sheng-Feng HUANG, Hsinchu (TW); Ching-Yu HUANG, Hsinchu (TW); Yuan-Yu HUANG, Hsinchu (TW); Meng-Hung SHEN, Hsinchu (TW); Wei-Cheng LIN, Hsinchu (TW); Jiann-Tyng TZENG, Hsinchu (TW)

(21) Appl. No.: 19/174,076

(22) Filed: Apr. 9, 2025

Related U.S. Application Data
(60) Provisional application No. 63/737,179, filed on Dec. 20, 2024.

(51) Int. Cl. H10D 30/62; H01L 25/07; H10D 30/00; H10D 30/01; H10D 62/10; H10D 80/20; H10D 84/80

(52) U.S. Cl. CPC H10D 30/62; H10D 30/024; H10D 30/501; H10D 62/121; H10D 80/251; H10D 84/811; H10W 90/00

(57) ABSTRACT

A cell region (of a semiconductor device) includes: first and second active regions on opposite sides of, and adjacent relative to, a first reference line, and being doped correspondingly with different dopants; and dummy gate segments each of which overlapping the active regions; corresponding AR-portions of the active regions being defined between adjacent ones of the dummy gate segments; each of the first and second active regions including adjacent first and second ones of the AR-portions; the first and second AR-portions defining first and second AR-sections; each of the first and second AR-sections having first and second profiles that correspondingly are proximal and distal to the first reference line; and the proximal profile of each of the first and second AR-sections being planar; and the distal profile of the first or second AR-section being stepped such that the first or second AR-section is a concave polygon shape.

### PRIORITY CLAIM

The application claims the priority of U.S. Provisional Application No. 63/737,179, filed Dec. 20, 2024, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a block diagram, in accordance with some embodiments.

FIGS. 2B-2B are corresponding layout diagrams, in accordance with some embodiments.

FIG. 3 is a layout diagram, in accordance with some embodiments.

FIGS. 4A-4D are corresponding layout diagrams, in accordance with some embodiments.

FIGS. 5A-5B are corresponding cross-sections, in accordance with some embodiments.

FIGS. 6 and 7 are flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a cell region (of a semiconductor device) includes: first and second active regions on opposite sides of, and adjacent relative to, a first reference line, and being doped correspondingly with different dopants; and dummy gate segments each of which overlapping the active regions; corresponding AR-portions of the active regions being defined between adjacent ones of the dummy gate segments; each of the first and second active regions including adjacent first and second ones of the AR-portions; the first and second AR-portions defining first and second AR-sections; each of the first and second AR-sections having first and second profiles that correspondingly are proximal and distal to the first reference line; and the proximal profile of each of the first and second AR-sections being planar; and the distal profile of the first or second AR-section being stepped such that the first or second AR-section is a concave polygon shape. In some embodiments, the cell region further includes: first and second dielectric structures correspondingly abutting first and second ends of the first gate segment; and third and fourth dielectric structures correspondingly abutting first and second ends of the second gate segment. A length of at least one of the first to fourth dielectric structures is different than other ones of the first to fourth dielectric structures. Consider a cell region according to another approach which is a counterpart to the present cell region.

The counterpart cell region has proximal profiles of the counterpart AR-sections that are planar and distal profiles of the counterpart AR-sections that are stepped. As a result of the counterpart distal profiles being planar and the height of the counterpart dielectric structures being uniform, the counterpart gate segments have the same length.

The effective capacitance of a cell region is dependent, among other things, upon gate-segment length. Due at least in part to the distal profile of present first AR-section being stepped or the distal profile of present second AR-section being stepped, one or more of the present have different lengths such that at least one of the present gate segments is shorter than the counterpart gate segment of the counterpart cell region. Accordingly, due to the different lengths of present gate segments, the effective capacitance of the present cell region is lower than the effective capacitance of the counterpart cell region. In some embodiments, the effective capacitance of the present cell region is in a range of about 2% to about 10% lower as compared to the effective capacitance of the counterpart cell region.

The threshold voltage (Vt) of a transistor is dependent, among other things, upon a distance between the AR-portion and an adjacent N/P boundary. Due to the proximal profile of each present first and second AR-sections being planar, the distances between the reference line each AR-portion of at least one vertically-adjacent pair of present AR-portions are smaller than the counterpart distances of the counterpart cell region. Accordingly, the threshold voltages for transistors in the at least one vertically-adjacent pair of present AR-portions are greater than counterpart threshold voltages for counterpart transistors in counterpart AR-portions of the counterpart cell region. Leakage of transistors in a cell region (cell region leakage) is inversely dependent, among other things, on threshold voltages of the transistors in the cell region. Accordingly, the leakage of present cell regions is lower than the leakage of the counterpart cell region. In some embodiments, the leakage of the present cell region is in a range of about 5% to about 30% lower as compared to leakage of the counterpart cell region.

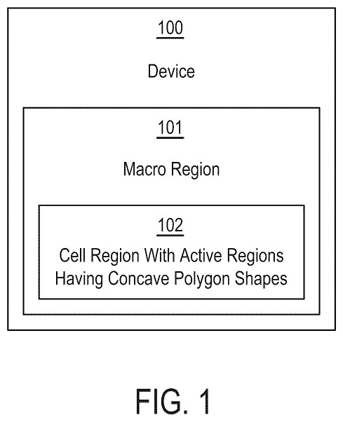

FIG. 1 is a block diagram of a cell region 102 of a device 100, in accordance with some embodiments.

Device 100 is an example of an integrated circuit (IC). In some embodiments, device 100 is referred to as a semiconductor device. Device 100 includes a macro region 101. Macro region 101 includes a functional cell region 102. In some embodiments, functional cell region 102 includes one or more active devices, passive devices, or the like. Examples of active devices or active elements include, but are not limited to, transistors, diodes, or the like. Examples of passive elements include, but are not limited to, capacitors, inductors, fuses, resistors, or the like.

In some embodiments, macro region 101 is comprised of one or more instances of functional cell region 102 and/or one or more other functional cell regions. In such embodiments, macro region 101 is configured to provide/execute a given computational function which is comprised of less complicated functions provided correspondingly by the instances of functional cell region 102 and/or the one or more other functional cell regions. In some embodiments, one or more instances of functional cell region 102 and/or one or more other functional cell regions represent intercoupled building blocks which comprise macro region 101.

In some embodiments, macro region 101 is understood in the context of an analogy to the architectural hierarchy of modular programming, in which subroutines/procedures are called by a main program (or by other subroutines) to carry out a given computational function. In this context, device 100 uses macro region 101 to perform one or more given functions. Accordingly, in this context and in terms of architectural hierarchy, device 100 is analogous to the main program and macro region 101 is analogous to subroutines/procedures. In some embodiments, macro region 101 is a soft macro. In some embodiments, macro region 101 is a hard macro. In some embodiments, macro region 101 is a soft macro which is described digitally in register-transfer level (RTL) code. In some embodiments, synthesis, placement, and routing have yet to have been performed on macro region 101 such that the soft macro can be synthesized, placed, and routed for a variety of process technology nodes. In some embodiments, macro region 101 is a hard macro which is described digitally in a binary file format (e.g., Graphic Database System II (GDSII) stream format), where the binary file format represents planar geometric shapes, text labels, other information, and the like of one or more layouts of macro region 101 in hierarchical form. In some embodiments, a binary file format is referred to as a non-text file format. In some embodiments, synthesis, placement, and routing have been performed on macro region 101 such that the hard macro is specific to a particular process technology node.

In some embodiments, examples of functions provided by a macro region (e.g., macro region 101) include a memory, a power grid, a clock tree, an adder, a phase-locked loop (PLL), a delay-locked loop (DLL), a flip-flop, a shift register, an analog-to-digital converter (ADC), a digital-to-analog converter (DAC), interfaces, higher-level Boolean logic, or the like. Example memories include a static random access memory (SRAM), a dynamic RAM (DRAM), a resistive RAM, a magnetoresistive RAM (MRAM), a read only memory (ROM), or the like. An example of a flip-flop is a scan-insertion type of D flip-flop (SDFQ), or the like. In some embodiments, examples of functions provided by functional cell regions (e.g., functional cell region 102) include an inverter, a tri-state inverter, a buffer, a latch a multiplexer (MUX), a driver, a latch, delay, a half adder, a full adder, a compressor, lower-level Boolean logic, or the like, Examples of lower-level Boolean logic include AND, OR, NAND, NOR, XOR, INV, AND-OR-Invert (AOI), OR-AND-Invert (OAI), or the like.

Functional cell region 102 includes corresponding segments in one or more metallization layers. Figures of the present disclosure assume a Cartesian coordinate system (unless noted otherwise) in which first, second and third directions are, e.g., correspondingly parallel to the X-axis, the Y-axis and the Z-axis. In some embodiments, the first to third directions correspond to directions other than the X-axis, Y-axis and Z-axis. In some embodiments, long and short axes of the segments extend correspondingly in the first and second directions in even ones of the metallization layers; in such embodiments, long and short axes of the segments extend correspondingly in the second and first directions in odd ones of the metallization layers. In such embodiments, boundaries of functional cell region 102 are described in terms of the first and second directions.

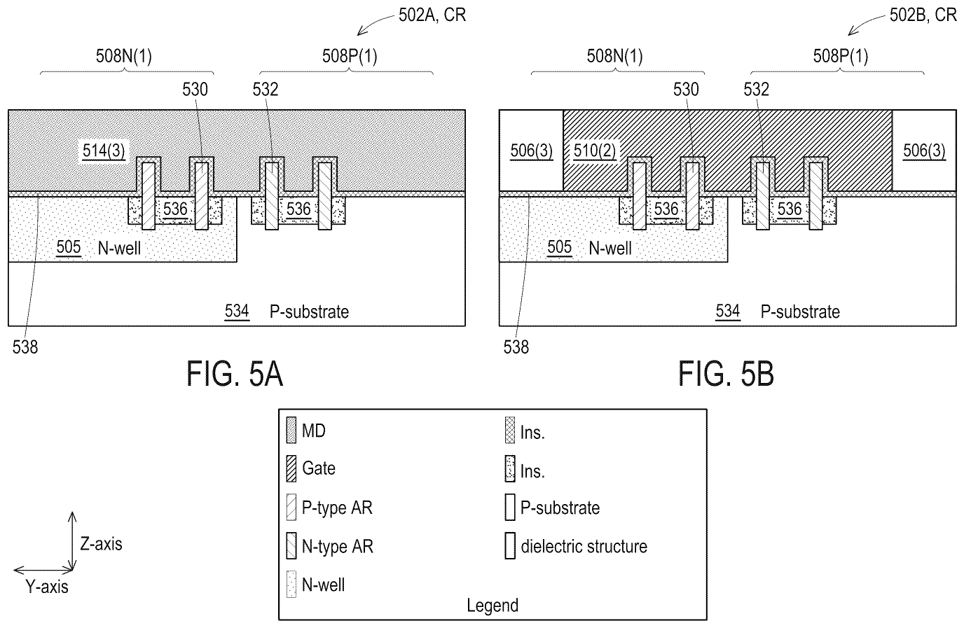

In some embodiments, functional cell region 102 corresponds to a transistor-components layer (see, e.g., FIGS. 5A-5B) having circuitry components, e.g., transistors, formed thereon in a front-end-of-line (FEOL) fabrication. In functional cell region 102, above and/or below an active region (AR) layer (see, e.g., FIGS. 5A-5B), various metal layers are interleaved with corresponding interconnection layers are stacked over and/or under insulating layers in a back end of line (BEOL) fabrication. The BEOL fabrication provides a power network and/or routing for circuitry of device 100, including macro region 101 and functional cell region 102.

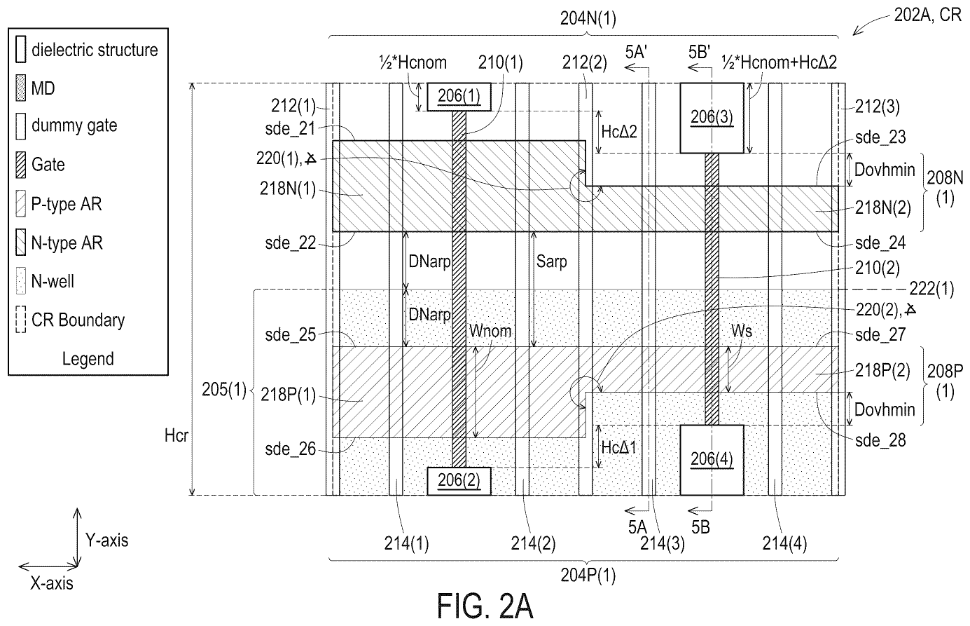

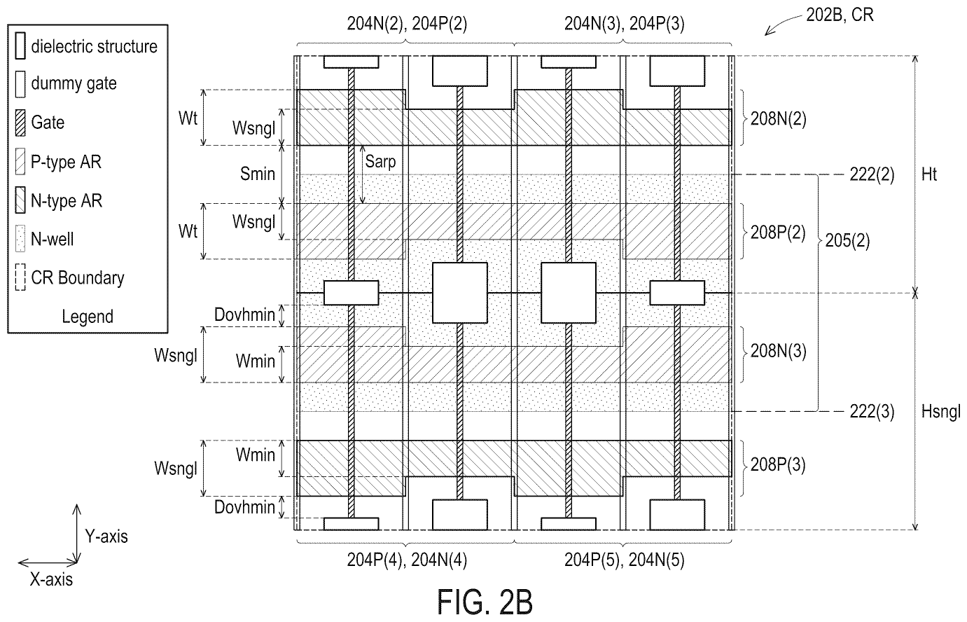

FIG. 2A is a layout diagram of a functional cell region (CR) 202A, in accordance with some embodiments.

Cell region 202A is an example of functional cell region 102 of FIG. 1. In FIG. 2A: section line 5A-5A′ corresponds to cross-section 502A of FIG. 5A; and section line 5B-5B′ corresponds to the cross-section 502B of FIG. 5B. Cell region 202A is arranged relative to the following: alpha track (or alpha lines) (not shown) that extend parallel to the X-axis, and beta tracks (beta lines) (not shown) that extend parallel to the Y-axis.

In FIG. 2A, and in other layout diagrams disclosed herein, the first and second directions are assumed to be parallel correspondingly to the X-axis and the Y-axis. In some embodiments, the first and second directions are assumed to have orientations other than being parallel correspondingly to the X-axis and the Y-axis. In FIG. 2A, and in other layout diagrams disclosed herein, rows extend parallel to the X-axis and overlap corresponding ones of the alpha tracks.

A transistor-based device is comprised of cell regions which are representable by layout diagrams of which the layout diagram of FIG. 2A, and other layout diagrams disclosed herein, are examples. Regarding transistors, examples which comprise a transistor-based device include field effect transistors (FETs). An example of an architecture for a transistor-based device is complementary metal-oxide-semiconductor (CMOS) architecture. The FETs include negative-channel metal-oxide semiconductor (NMOS) FETs (NFETs) and positive-channel metal-oxide semiconductor (PMOS) FETS (PFETs). Regarding CMOS architecture, examples of FET architectures include planar field-effect transistor (FET) architecture, finFET architecture, gate-all-around FET (GAAFET) architectures, or the like. Examples of the GAAFET architecture include as nanowire architecture, nanosheet architecture, forksheet architecture, or the like.

Structures in a transistor-based device are represented by patterns (also known as shapes) in the layout diagram. For simplicity of discussion, elements in the layout diagrams of FIG. 2A and other layout diagrams disclosed herein will be referred to as if they are structures rather than patterns. For example, shapes in FIG. 2A representing instances of gate segments are referred to as gate segments per se rather than as gate shapes.

A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. The layout diagrams disclosed herein are examples of layout diagrams in which selected layers and/or selected elements of depicted given layers, have been omitted.

Depending upon the numbering convention of the corresponding process technology node by which a device is to be fabricated, on a front side of the device the first layer metallization is either metallization layer zero (MET0) or metallization layer one (MET1), and correspondingly a first interconnection layer on the first metallization layer is either interconnection layer zero (VIA0) or interconnection layer one (VIA1). In such embodiments, again depending upon the numbering convention of the corresponding process technology node, on a back side (not shown) of the device, the first buried metallization layer is either buried metallization layer zero (BMET0) or buried metallization layer one (BMET1), and correspondingly a first buried interconnection layer under the first metallization layer is either interconnection layer zero (VIA0) or interconnection layer one (VIA1).

In general regarding the figures disclosed herein (unless noted otherwise), the following nomenclature is adopted regarding the front side of a device: the first metallization layer is assumed to be MET0; the first interconnection layer is assumed to be VIA0; the second metallization layer is assumed to be MET1; the second interconnection layer is assumed to be VIA1; and the third metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

In general, regarding the figures disclosed herein (unless noted otherwise), or the like, the following nomenclature is adopted regarding the back side of a device: the first buried metallization layer is assumed to be BMET0; the first buried interconnection layer is assumed to be BVIA0; the second buried metallization layer is assumed to be BMET1; the second buried interconnection layer is assumed to be BVIA1; and the third buried metallization layer is assumed to BMET2. Metallization segments in layer BMET0 are referred to as buried M0 (BM0) segments. Via structures in layer BVIA0 are referred to as BV0 structures. Metallization segments in layer BMET1 are referred to as buried M1 (BM1) segments. Via structures in layer BVIA1 are referred to as BV1 structures. Metallization segments in layer BMET2 are referred to as buried M2 (BM2) segments.

In FIG. 2A, cell region 202A includes: a negative-type (n-type) active region 208N(1) that extends substantially parallel to the X-axis and is used for corresponding NFETs; an n-type well (N-well) 205(1); a positive-type (p-type) active region 208P(1) that extends substantially parallel to the X-axis, is in N-well 205(1), and is used for corresponding PFETs; gate segments 210(1)-210(2) that extend substantially parallel to the Y-axis; dummy gate segments 212(1)-212(3) that extend substantially parallel to the X-axis; metal-to-source/drain contact (MD) structures 214(1)-214(4) that extend substantially parallel to the X-axis; and cut-gate (CG) shapes (or patterns) 206(1)-206(4) (also referred to as dielectric structures 206(1)-206(4)). It is understood that the portion of a corresponding gate segment (e.g., 210(1) or 210(2)) which is overlapped by a given CG shape (e.g., 206(1)-206(4)) will be removed during fabrication of a corresponding semiconductor device based on a layout diagram (e.g., the layout diagram of FIG. 2A) which includes the given CG shape. As such, in some embodiments, each CG shape (e.g., 206(1)-206(4)) represents a dielectric structure (discussed below) that replaces the portion of the corresponding gate segment (e.g., 210(1)-210(2) which is overlapped by the CG shape (e.g., 206(1)-206(4)). In some embodiments, dielectric structures 206(1)-206(4) are referred to as cut-gate (CG) structures 206(1)-206(4). In some embodiments, dielectric structures 206(1)-206(4) are described as byproducts that result from trimming portions of the precursors of the gate segments, e.g., the precursors of gate segments 210(1) and 210(2), that underlie the corresponding CG shapes (e.g., 206(1)-206(4)).

In some embodiments, a dummy gate segment (e.g., 212(1)-212(3)) is a gate segment that is not coupled to voltage source. In some embodiments, a dummy gate segment is a gate segment that is not coupled to a voltage source, e.g., VDD, VSS or the like. In some embodiments, a dummy gate segment is an isolation dummy gate (IDG) structure. In some embodiments, an isolation dummy gate (IDG) structure is a dielectric structure that includes one or more dielectric materials and functions as an electrical isolation structure. Accordingly, an IDG structure is not a structure that is electrically conductive and thus does not function, e.g., as an active gate of a transistor. An IDG structure includes one or more dielectric materials and functions as an electrical isolation structure. In some embodiments, an IDG structure is based on a gate segment as a precursor. In some embodiments, an IDG structure is based on a dummy gate structure. In some embodiments, a dummy gate structure includes a gate segment that is decoupled so as to not function, e.g., as a gate of a transistor, a gate-insulator layer, (optionally) one or more spacers, or the like. In some embodiments, an IDG structure is formed by first forming a gate segment e.g., which is included in a dummy gate structure, sacrificing/removing (e.g., etching) the gate segment to form a trench, (optionally) removing a portion of a substrate that previously had been under or over or around the gate segment to deepen the trench, and then filling the trench with one or more dielectric materials such that the physical dimensions of the resultant electrical isolation structure, i.e., the IDG, are similar to the dimensions of the gate segment which was sacrificed. In some embodiments, an IDG is a dielectric feature that includes one or more dielectric materials (e.g., oxide, nitride, oxynitride, or other suitable materials), and functions as an isolation feature. In some embodiments, an IDG is a continuous polysilicon on oxide diffusion (OD) edge structure, and is referred to as a CPODE structure.

In FIG. 2A, active regions 208N(1) and 208P(1) are on opposite sides of a reference line 222(1) extending parallel to the X-axis, and are adjacent relative to the Y-axis (vertically-adjacent). FIG. 2A assumes that reference line 222(1) represents a boundary between the NMOS and PMOS regions of cell region 202A. In some embodiments, reference line 222(1) does not represent the boundary between the NMOS and PMOS regions of cell region 202A. FIG. 2A also assumes that reference line 222(1) represents a boundary of N-well 205(1). In some embodiments, the boundary of an N-well (e.g., reference line 222(1)) is referred to as a N/P boundary or as a P/N boundary. In some embodiments, reference line 222(1) does not represent a boundary of an N-well.

Each of gate segments 210(1)-210(2), dummy gate segments 212(1)-212(3) and MD structures 214(1)-214(4) overlaps each of active regions 208N(1) and 208P(1). Where a part of one of MD structures 214(1)-214(4) overlaps an active region (e.g., active regions 208N(1) and 208P(1)), the correspondingly overlapped sub-region of the active region is relatively more heavily doped to serve as a source/drain (S/D) region of a corresponding transistor. Where a part of one of gate segments 210(1)-210(2) overlaps an active region (e.g., active regions 208N(1) and 208P(1)), the correspondingly overlapped sub-region of the active region is configured to serve as a channel region of a corresponding transistor. As such, the gate-segment-overlapped sub-region of the active region is free from being relatively more heavily doped as compared, e.g., to an S/D region.

Corresponding AR-portions of active regions 208N(1) and 208P(1) are defined between adjacent ones of dummy gate segments 212(1)-212(3) relative to the X-axis (horizontally-adjacent). Active region 208N(1) includes AR-portions 218N(1) and 218N(2). Active region 208P(1) includes AR-portions 218P(1) and 218P(2). Each pair of horizontally-adjacent AR-portions defines a corresponding AR section. As such, AR-portions 218N(1) and 218N(2) define AR-section 204N(1) of active region 208N(1), and AR-portions 218P(1) and 218P(2) define AR-section 204P(1) of active region 208P(1).

In some embodiments, relative to the Y-axis: cell region 202A is stacked over (e.g., abutted over) another cell region, e.g., another instance of cell region 202A or a different cell region; and/or cell region 202A is stacked under (e.g., abutted under) another cell region, e.g., another instance of cell region 202A or a different cell region. In some embodiments, relative to the X-axis: cell region 202A is left-adjacent (e.g., leftward abuts) another cell region, e.g., another instance of cell region 202A or a different cell region; and/or cell region 202A is right-adjacent (e.g., rightward abuts) another cell region, e.g., another instance of cell region 202A or a different cell region.

Relative to the Y-axis: AR-portion 218N(1) has sides sde_21 and sde_22; AR-portion 218N(2) has sides sde_23 and sde_24; AR-portion 218P(1) has sides sde_25 and sde_26; and AR-portion 218P(2) has sides sde_27 and sde_28. Each of sides sde_21-sde_28 is substantially planar. Sides sde_21-sde_s7 are substantially parallel. Sides sde_22 and sde_24 are substantially collinear. Sides sde_21 and sde_23 are not substantially collinear. Sides sde_25 and sde_27 are substantially collinear. Sides sde_26 and sde_28 are not substantially collinear.

In terms of distance from reference line 222(1) as measured from the Y-axis: side sde_22 is proximal whereas side sde_21 is distal; side sde_24 is proximal whereas side sde_23 is distal; side sde_25 is proximal whereas side sde_26 is distal; and side sde_27 is proximal whereas side sde_28 is distal.

In terms of distance from reference line 222(1) as measured from the Y-axis: AR-section 208N(1) has a proximal profile comprised of sides sde_22 and sde_24 and a distal profile comprised of sides sde_21 and sde_23; and AR-section 208P(1) has a proximal profile comprised of sides sde_25 and sde_27 and a distal profile comprised of sides sde_26 and sde_28. The proximal profile of AR-section 208N(1) is substantially planar. The distal profile of AR-section 208N(1) is stepped. The proximal profile of AR-section 208P(1) is substantially planar. The distal profile of AR-section 208P(1) is stepped.

Each of AR-sections 204N(1) and 204P(1) has a concave polygon shape. In some embodiments, a concave polygon is defined as a polygon having one or more interior angles greater than 180 degrees (180°). AR-section 204N(1) has an interior angle 220(1), where [symbol] _220(1)≈270°. AR-section 204P(1) has an interior angle 220(2), where [symbol] _220(1)≈270°.

Relative to the Y-axis: each of AR-portions 218N(1) and 218P(1) has a width Wnom; and each of AR-portions 218N(1) and 218P(1) has a width Ws, where width Ws is different than width Wnom such that Ws<Wnom. Width Ws is equal to or greater than a width Wmin such that Wmin≤Ws<Wnom, where width Wmin is a minimum width of an active region as set by one or more design rules according to a corresponding semiconductor process technology node.

The difference between widths Wnom and Ws, HcΔ1, represents a step size of each of AR-sections 204N(1) and 204P(1) such that HcΔ1=Wnom−Ws, and where 0<Wmin≤HcΔ1. In some embodiments, the step size is referred to as a jog size.

Relative to the Y-axis, cell region 202A has a height Hcr and AR-portions 218N(1) & 218P(2) and 218N(2) & 218P(2) are separated by a gap, i.e., an inter-AR-portion distance, having a size Sarp; and size Sarp is the sum of a distance DNarp and a distance DParp. Distance DNarp is from reference line 222(1) to each of side sd_22 of AR-portion 218N(1) and side sde_24 of AR-portion 218N(2). Distance DParp is from reference line 222(1) to each of side sd_25 of AR-portion 218P(1) and side sde_27 of AR-portion 218P(2). FIG. 2A assumes that distance DNarp is substantially equal to distance DParp such that DNarp≈DParp.

Size Sarp is equal to or greater than a size Smin such that Smin≤Sarp, where width Smin is a minimum distance as set by one or more design rules according to a corresponding semiconductor process technology node.

In FIG. 2A, relative to the Y-axis, each of the gate segments 210(1) and 210(2) overhangs the distal profiles of AR-sections 204N(1) and 204P(1) by a substantially uniform overhang-distance Dovh. In FIG. 2A, distance Dovh is assumed to be substantially equal to a minimum overhang distance Dovhmin, where distance Dovhmin is a minimum distance for gate segment overhangs as set by one or more design rules of a corresponding semiconductor process technology node. In some embodiments, Dovhmin<Dovh.

In FIG. 2A, gate-segment length is considered relative to the Y-axis. Gate segment 210(1) is longer than gate segment 210(2). Because the distal profile of AR-section 204N(1) is stepped, the end of gate segment 210(2) which overhangs AR-portion 218N(2) is not as far from reference line 222(1) as the end of gate segment 210(1) which overhangs AR-portion 218N(1). Because the distal profile of AR-section 204P(1) is stepped, the end of gate segment 210(2) which overhangs AR-portion 218P(2) is not as far from reference line 222(1) as the end of gate segment 210(1) which overhangs AR-portion 218P(1). As such, a length of gate segment 210(2), L_210(2), is smaller than a length of gate segment 210(1), L_210(1), such that L_210(1)<L_210(2).

In FIG. 2A, ends of gate segment 210(1) correspondingly are abutted to dielectric structures 206(1) and 206(2). Ends of gate segment 210(2) are correspondingly abutted to dielectric structures 206(3) and 206(4). In some embodiments, dielectric structures 206(1)-206(4) are formed of a dielectric material (e.g., a dielectric material) that is different than interstitial material (not shown) which fills interstitial space around dielectric structures 206(1)-206(4), e.g., the interstitial material being another dielectric material. In some embodiments, dielectric structures 206(1) are formed of a nitride material whereas the interstitial material is an oxide, or vice versa. In some embodiments, dielectric structures 206(1)-206(4) are formed of a material that is the same as the interstitial material such that dielectric structures 206(1)-206(4) are more easily discerned (or identified) in the corresponding layout diagram than in the device manufactured according to the layout diagram.

Relative to the Y-axis, a height of each of dielectric structures 206(1)-206(4) varies in order to achieve an overhang distance Dovhmin for the corresponding end of the corresponding gate segment. In general, the height of dielectric structures 206(1)-206(4) is inversely proportional to the width of the corresponding AR-portion. As each of AR-portions 218N(1) and 218P(1) has width Wnom, the height of each of dielectric structures 206(1) and 206(2) correspondingly is ½*Hcnom.

FIG. 2A assumes that Hcnom is Hcmin, where Hcmin is a minimum height for dielectric structures (e.g., 206(1)-206(4)) as set by one or more design rules of a corresponding semiconductor process technology node. In some embodiments, Hcmin<Hcnom. As each of AR-portions 218N(2) and 218P(2) has width Ws, the height of each of dielectric structures 206(3) and 206(4) is relatively greater than the height of each of AR-portions 218N(1) and 218P(1). As such the height of each of dielectric structures 206(3) and 206(4) correspondingly is ½*Hcnom+HcΔ2. Regarding distance Dovhmin of each overhanging end part of each of gate segments 210(1) and 210(2), Dovhmin=½*(Smin−Hcmin). Height Hcr of cell region is Hcr≤2*(Wnom+Smin).

Consider a cell region according to another approach which is a counterpart to cell region 202A. The counterpart cell region has counterparts to AR-sections 204N(1) and 204P(1) and counterparts to gate segments 210(1)-210(2). The proximal profiles of the counterpart AR-sections are planar and the distal profiles of the counterpart AR-sections are stepped. The counterpart cell region has counterparts to dielectric structures 206(1)-206(4), where the counterpart dielectric structures are of uniform height. As a result of the counterpart distal profiles being planar and the height of the counterpart dielectric structures being uniform, the counterpart gate segments have the same length.

The effective capacitance of a cell region is dependent, among other things, upon gate-segment length. Due at least in part to the distal profile of AR-section 204N(1) being stepped and the distal profile of AR-section 204P(1) being stepped, gate segments 210(1) and 210(2) have different lengths such that gate segment 210(2) is shorter than the counterpart gate segment of the counterpart cell region. Accordingly, due to the different lengths of gate segments 210(1) and 210(2), the effective capacitance of cell region 202A is lower than the effective capacitance of the counterpart cell region. In some embodiments, the effective capacitance of cell region 202A is in a range of about 2% to about 10% lower as compared to the effective capacitance of the counterpart cell region. Other cell regions disclosed herein beneficially exhibit similarly reduced effective capacitances as compared to corresponding counterpart cell regions.

The threshold voltage (Vt) of a transistor is dependent, among other things, upon a distance between the AR-portion and an adjacent N/P boundary. Due to the proximal profile of each AR-sections 204N(1) and 204P(1) being planar, the distances between AR-portion 218N(2) and 218P(2) and reference line 222(1) are smaller than the counterpart distances of the counterpart cell region. Accordingly, the threshold voltages for transistors in AR-portions 218N(2) and 218P(2) are greater than counterpart threshold voltages for counterpart transistors in counterpart AR-portions of the counterpart cell region. Leakage of transistors in a cell region (cell region leakage) is inversely dependent, among other things, on threshold voltages of the transistors in the cell region. Accordingly, the leakage of cell region 202A is lower than the leakage of the counterpart cell region. In some embodiments, the leakage of cell region 202A is in a range of about 5% to about 30% lower as compared to leakage of the counterpart cell region. Other cell regions disclosed herein beneficially exhibit similarly reduced leakages as compared to corresponding counterpart cell regions.

FIG. 2B is a layout diagram of a functional cell region (CR) 202B, in accordance with some embodiments.

Cell region 202B is similar to cell region 202A of FIG. 2A. For purposes of brevity, the discussion will focus on differences of cell region 202B as compared to cell region 202A rather than on similarities. In general, as compared to cell region 202A: cell region 202B has more AR-portions and AR-sections; and more variety in the widths of the AR-portions.

Cell region 202B includes: active regions 208N(2), 208N(3), 208P(2) and 208P(3); N-well 205(2); reference lines 222(2) and 222(3); and AR-sections 204N(2), 204N(3), 204N(4), 204N(5), 204P(2), 204P(3), 204P(4) and 204P(5).

Each of active regions 208N(2) and 208P(2) includes tall AR-portions having a width Wt and AR portions having a single-cell width Wsngl. In some embodiments, width Wt is in a range Wnom≤Wt≤(≈3*Wnom).

Each of active regions 208N(3) and 208P(3) includes tall AR-portions having a width Wt and AR portions having a single-cell width Wsngl. In some embodiments, width Wsngl is in a range (≈0.8*Wnom)≤Wt≤(≈1.2*Wnom).

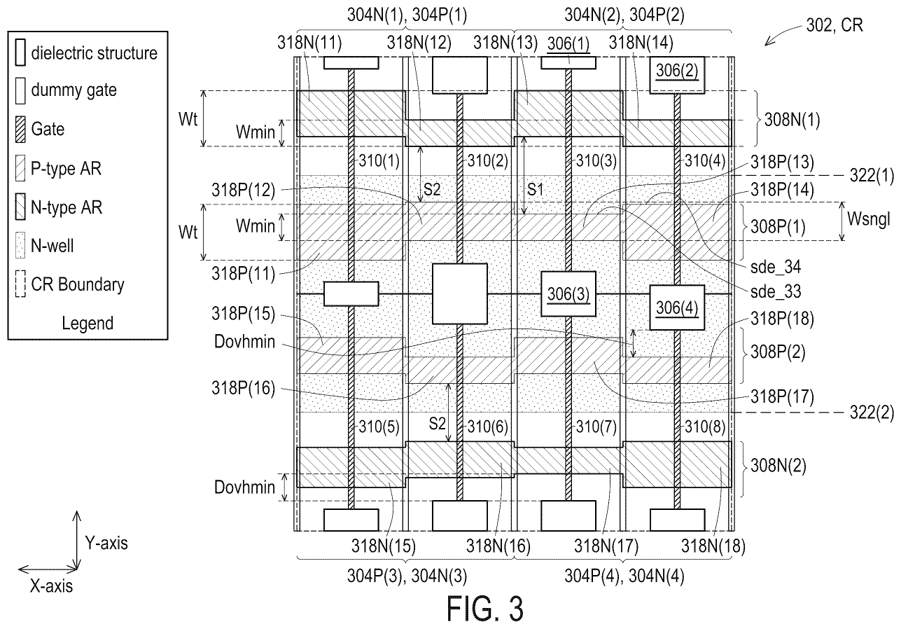

FIG. 3 is a layout diagram of a functional cell region (CR) 302, in accordance with some embodiments.

Cell region 302 is similar to cell region 202B of FIG. 2B. For purposes of brevity, the discussion will focus on differences of cell region 302 as compared to cell region 202B rather than on similarities. In general, as compared to cell region 202B, cell region 302 has different values of inter-AR-portion distance than cell region 202B, the latter having uniform inter-AR-portion distance Sarp.

For simplicity of illustration of FIG. 3, not all structures are labeled. Cell region 302 includes: active regions 308N(1), 308N(2), 308P(1) and 308P(2); an N-well; reference lines 322(1) and 322(2); and AR-portions 318N(11), 318N(12), 318N(13), 318N(14), 318N(15), 318N(16), 318N(17), 318N(18), 318P(11), 318P(12), 318P(13), 318P(14), 318P(15), 318P(16), 318P(17) and 318P(18); and AR-sections 304N(1), 304N(2), 304N(3), 304N(4), 304P(1), 304P(2), 304P(3) and 304P(4). The dielectric structures include dielectric structures 306(1)-306(4).

Relative to reference line 322(1): AR-portion 318N(13) has a proximal side sd_31; AR-portion 318N(14) has a proximal side sd_32; AR-portion 318P(13) has a proximal side sd_33; and AR-portion 318P(14) has a proximal side sd_34.

Cell region 302 includes two values of inter-AR-portion distance, namely S1 and S2. For example, sides sde_31 and sde 33 are separated by inter-AR-portion distance S1 and sides sde_33 and sde_34 are separated by inter-AR-portion distance S2, where Smin≤S2<S1.

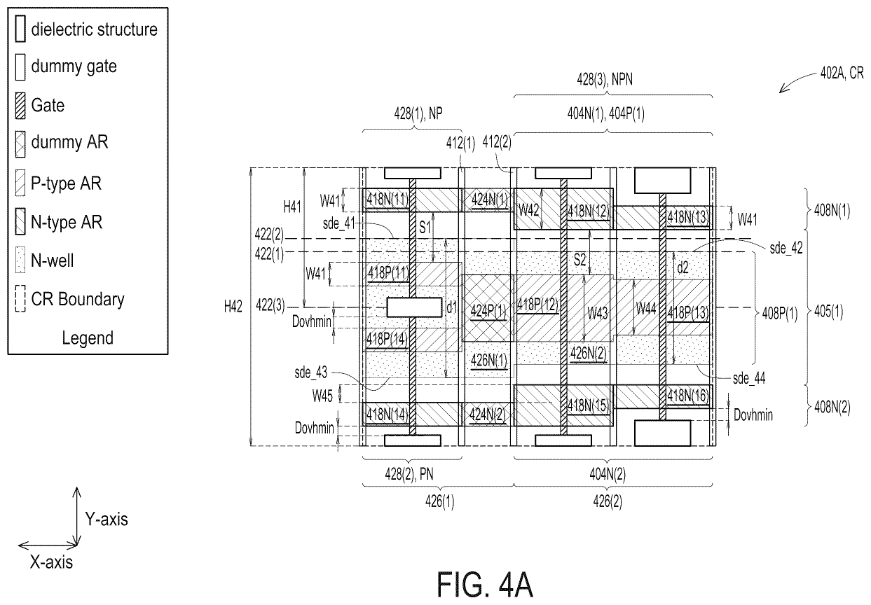

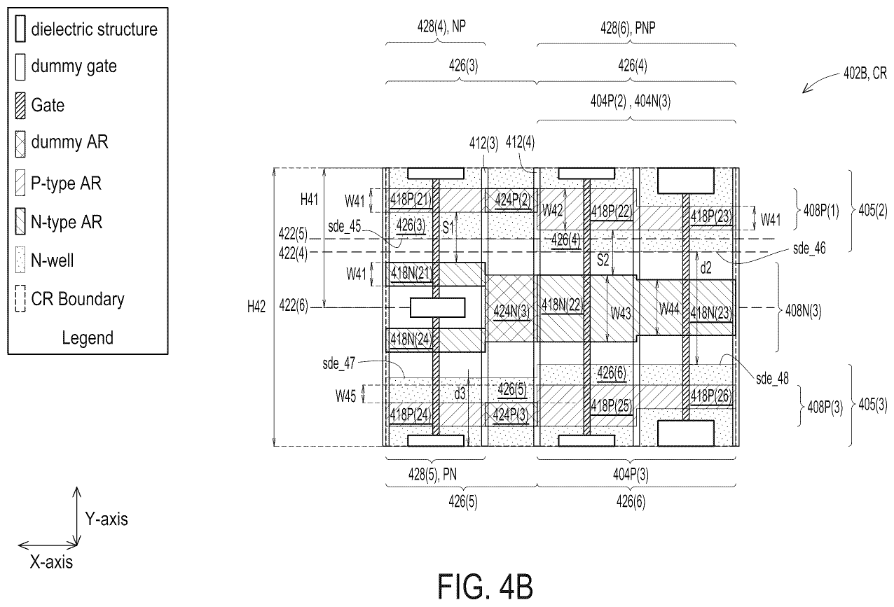

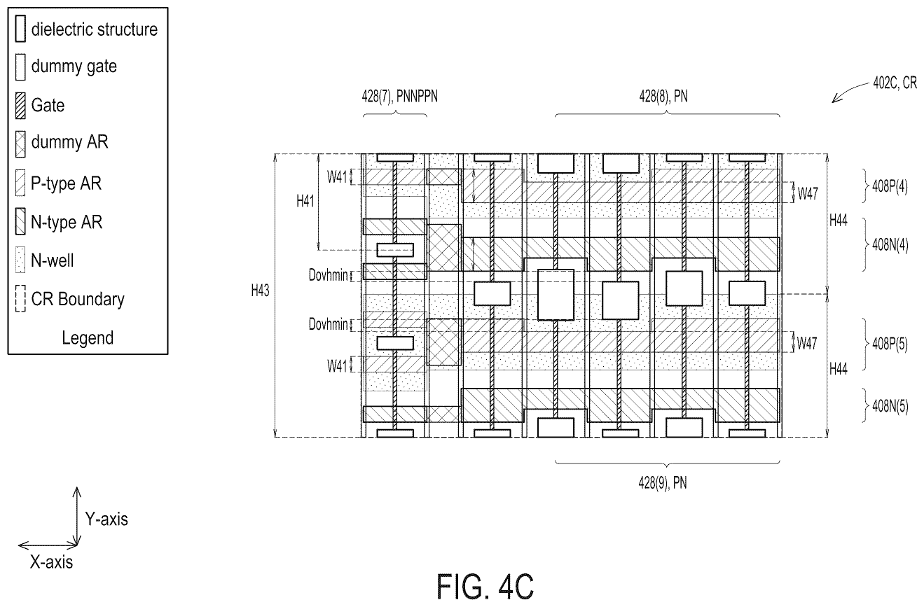

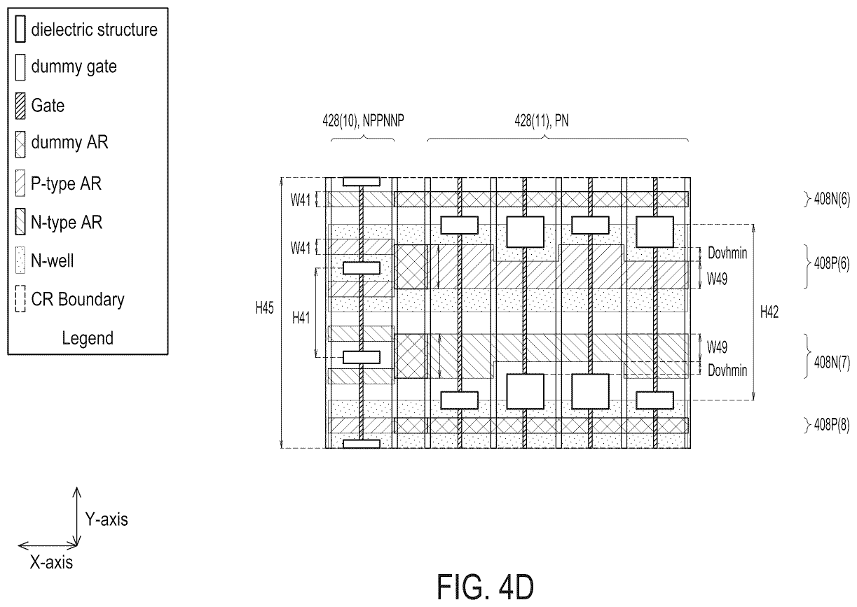

FIG. 4A is a layout diagram of a functional cell region (CR) 402A, in accordance with some embodiments.

Cell region 402A is similar to cell region 302 of FIG. 3. For purposes of brevity, the discussion will focus on differences of cell region 402A as compared to cell region 302 rather than on similarities. In general, as compared to cell region 302, cell region 402A includes dummy AR-portions and an N-well of varying widths.

For simplicity of illustration of FIG. 4A, not all structures are labeled. Cell region 402A includes: active regions 408N(1), 408N(2), 408P(1) and 408P(2); an N-well 405(1); reference lines 422(1), 422(2) and 422(3); AR-portions 418N(11), 418N(12), 418N(13), 418N(14), 418N(15), 418N(16), 418P(11), 418P(12), 418P(13) and 418P(14); dummy AR-portions (DAR-portions) 424N(1), 424N(2) and 424P(3); and AR-sections 404N(1), 404N(2) and 404P(1). N-well 405(1) includes NW-portions 426(1) and 426(2). The dummy gates include dummy gates 412(1) and 412(2).

AR-portions 418N(11) and 418P(11) represent a CR-portion 428(1) of cell region 402A. Relative to the Y-axis, CR-portion 428(1) has an NMOS-PMOS (NP) arrangement. AR-portions 418P(14) and 418N(14) represent a CR-portion 428(2) of cell region 402A. Relative to the Y-axis, CR-portion 428(2) has a PMOS-NMOS (PN) arrangement. Together, AR-sections 404N(1), 404P(1) and 404N(2) represent a CR-portion 428(3) of cell region 402A. Alternatively, AR-portions 418N(12)-418N(13), 418P(12)-418P(13) and 418N(15)-418N(16) represent CR-portion 428(3) of cell region 402A. Relative to the Y-axis, CR-portion 428(3) has an NMOS-PMOS-NMOS (NPN) arrangement.

Relative to the Y-axis: NW-portion 426(1) has an upper side sde_41 and a lower side sde_43; NW-portion 426(1) has a width d1; NW-portion 426(2) has an upper side sde_42 and a lower side sde_44; and NW-portion 426(2) has a width d2. NW-portion 426(2) is narrower than NW-portion 426(1) such that d2<d1.

Relative to X-axis, each DAR-portion extends between corresponding adjacent dummy gates. In FIG. 4A, each of DAR-portions 424N(1), 424N(2) and 424P(1) extends between dummy gates 412(1) and 412(2). In some embodiments, a DAR-portion is defined as an AR-portion which is free of having a source/drain (S/D) region therein, i.e., is free from having a region therein that is relatively more heavily doped as compared, e.g., to an S/D region. In some embodiments, a DAR-portion is defined as an AR-portion which is free from having an overlying gate segment. Each DAR-portion serves as an isolation structure. DAR-portion 424N(1) isolates AR-portion 418N(11) from AR-portion 418N(12). DAR-portion 424P(2) isolates each of AR-portions 418P(11) and 418P(14) from AR-portion 418P(12). DAR-portion 424N(2) isolates AR-portion 418N(14) from AR-portion 418N(15).

In FIG. 4A, relative to the Y-axis, each of CR-portions 428(1) and 428(2) has a height H41 and cell region 402A has a height H42, where H42=(≈2.0*H41); width W41 is in a range Wmin≤W41≤W42; width W42 is W42=W41+n*W45, where n is a positive integer, W42≤(≈1.5*W42) and W45 is a width the jog between each of (A) AR-portions 418N(12) and 418N(13) and (B) AR-portions 418N(15) and 418N(16); width W43 is in a range (≈1.5*W41)≤W43≤(≈2.0*W41); and width W44 is in a range (≈1.5*W41)≤W44≤(≈W43).

FIG. 4B is a layout diagram of a functional cell region (CR) 402B, in accordance with some embodiments.

Cell region 402B is similar to cell region 402A of FIG. 4A. For purposes of brevity, the discussion will focus on differences of cell region 402B as compared to cell region 402A rather than on similarities. In general, as compared to cell region 402A, the NMOS and PMOS regions are reversed and accordingly there are two N-wells rather than one.

For simplicity of illustration of FIG. 4B, not all structures are labeled. Cell region 402B includes: active regions 408P(2), 408P(3) and 408N(3); N-wells 405(2) and 405(3); reference lines 422(4), 422(5) and 422(6); and AR-portions 418P(21), 418P(22), 418P(23), 418P(24), 418P(25), 418P(26), 418N(21), 418N(22), 418N(23) and 418N(14); DAR-portions 424P(2), 424P(3) and 424N(3); and AR-sections 404P(2), 404P(3) and 404N(3). N-well 405(2) includes NW-portions 426(3) and 426(4). N-well 405(3) includes NW-portions 426(5) and 426(6). The dummy gates include dummy gates 412(3) and 412(4).

AR-portions 418P(21) and 418N(21) represent a CR-portion 428(4) of cell region 402B. Relative to the Y-axis, CR-portion 428(4) has a PMOS-NMOS (PN) arrangement. AR-portions 418N(24) and 418P(24) represent a CR-portion 428(5) of cell region 402B. Relative to the Y-axis, CR-portion 428(5) has an NMOS-PMOS (PN) arrangement. Together, AR-sections 404P(2), 404N(3) and 404P(3) represent a CR-portion 428(6) of cell region 402B. Alternatively, AR-portions 418P(22)-418P(23), 418N(22)-418N(23) and 418P(25)-418P(26) represent CR-portion 428(6) of cell region 402B. Relative to the Y-axis, CR-portion 428(6) has PMOS-NMOS-PMOS (PNP) arrangement.

Relative to the Y-axis: NW-portion 426(3) has a lower side sde_45; NW-portion 426(3) has a width d3; NW-portion 426(4) has a lower side sde_46; NW-portion 426(4) has a width d4; NW-portion 426(5) has an upper side sde_47; NW-portion 426(5) has a width d3; NW-portion 426(6) has an upper side sde_47; and NW-portion 426(5) has a width d4. NW-portion 426(3) is narrower than NW-portion 426(4), and NW-portion 426(5) is narrower than NW-portion 426(6), such that d3<d4.

Relative to X-axis, each DAR-portion extends between corresponding adjacent dummy gates. In FIG. 4B, each of DAR-portions 424N(1), 424N(2) and 424P(1) extends between dummy gates 412(1) and 412(2). DAR-portion 424P(2) isolates AR-portion 418P(21) from AR-portion 418P(22). DAR-portion 424N(3) isolates each of AR-portions 418N(21) and 418N(24) from AR-portion 418N(22). DAR-portion 424P(3) isolates AR-portion 418(24) from AR-portion 418P(25).

In FIG. 4B, the relationships between H41 and H42, and amongst widths W41-W45 are the same as in FIG. 4A.

FIG. 4C is a layout diagram of a functional cell region (CR) 402C, in accordance with some embodiments.

A first part of cell region 402C is similar to a part of cell regions 402A of FIG. 4A and 402B of FIG. 4B. A second part of cell region 402C is similar to a part of cell region 202B of FIG. 2B. For purposes of brevity, the discussion will focus on differences of cell region 402C as compared to cell regions 402A and 202B rather than on similarities.

For simplicity of illustration of FIG. 4C, not all structures are labeled. Among other components, cell region 402C includes: active regions 408P(4), 408P(5), 408N(4) and 408N(5); and CR-portions 428(7), 428(8) and 428(9).

The first part of cell region 402C mentioned above is represented by CR-portion 428(7). CR-portion 428(7) is similar to each of CR-portion 428(1) of cell region 404A and cell region 427(4) of cell region 404B but has additional NMOS and PMOS regions that are in a different vertical arrangement. Relative to the Y-axis, CR-portion 438(7) is comprised of three sub-CR-portions stacked on each other including: a first sub-CR-portion having a PN arrangement; a second sub-CR-portion having an NP arrangement; and a third sub-CR-portion having a PN arrangement. Each of the first, second and third sub-CR-portions of CR-portion 428(7) has a height H41. As such, CR-portion 428(7) has an arrangement PNNPPN.

The second part of cell region 402C mentioned above is represented by CR-portions 428(8) and 428(9). While CR-portions 428(8) and 428(9) considered in combination are similar to cell region 202B, nonetheless differences exhibited by the combination of CR-portions 428(8) and 428(9) include the following: the NMOS and PMOS regions are reversed which resultingly increases the number of N-wells; and the numbers of NMOS and PMOS regions are greater than in cell region 202B.

Relative to the Y-axis: each of CR-portions 428(8) and 428(9) has a PN arrangement, and the combination of CR-portions 428(8) and 428(9) has a PNPN arrangement.

In FIG. 4C, relative to the Y-axis: cell region 402C has a height H43, where H43=(≈3.0*H41); and each of CR-portions 428(8) and 429(9) has a height H44, where H44=(≈1.5*H41); width W46 is in a range (≈1.5*W41)≤W46≤(≈2.5*W41); and width W47 is in a range (≈0.8*W41)≤W47≤(≈W46).

FIG. 4D is a layout diagram of a functional cell region (CR) 402D, in accordance with some embodiments.

A first part of cell region 402D is similar to a part of cell region 402C of FIG. 4C. A second part of cell region 402D is similar to a part of cell region 202A of FIG. 2A. For purposes of brevity, the discussion will focus on differences of cell region 402D as compared to cell regions 402C and 202A rather than on similarities.

For simplicity of illustration of FIG. 4D, not all structures are labeled. Among other components, cell region 402D includes: active regions 408N(6), 408N(7), 408P(6) and 408P(7); and CR-portions 428(10) and 428(11).

The first part of cell region 402D mentioned above is represented by CR-portion 428(10). CR-portion 428(10) is similar to CR-portion 428(7) of cell region 404C but has the NMOS and PMOS regions in a different vertical arrangement. Relative to the Y-axis, CR-portion 438(10) is comprised of three sub-CR-portions stacked on each other including: a first sub-CR-portion having an NP arrangement; a second sub-CR-portion having a PN arrangement; and a third sub-CR-portion having an NP arrangement. Each of the first, second and third sub-CR-portions of CR-portion 428(1) has a height H41. As such, CR-portion 428(10) has an arrangement NPPNNP.

The second part of cell region 402D mentioned above is represented by CR-portion 428(11). While CR-portion 428(11) is similar to cell region 202A, nonetheless differences exhibited by CR-portion 428(11) include the following: the NMOS and PMOS regions are reversed which resultingly increases the number of N-wells; and the numbers of NMOS and PMOS regions are greater than in cell region 202A. Relative to the Y-axis, CR-portion 428(11) has a PN arrangement.

In FIG. 4D, relative to the Y-axis: cell region 402D has a height H45, where H45=(≈(H41+H42))=(≈(2.0*(½*H41)+H42)); width W48 is in a range (≈1.5*W41)≤W48≤(≈4.5*W41); and width W49 is in a range (≈0.8*W41)≤W49≤(≈W48).

FIGS. 5A and 5B are corresponding cross sectional views 502A and 502B of a functional cell region, in accordance with some embodiments.

In particular, FIGS. 5A-5B are cross sectional views of a cell region based on cell 202A of FIG. 2A. FIGS. 5A-5B correspond to section lines 5A-5A′ and 5B-5B′ of FIG. 2.

Each of FIGS. 5A-5B includes: a P-type substrate 534; N-well 505 formed in substrate 534; P-type fins 530 formed partially in N-well 505 relative to the Z-axis; N-type fins 532 formed partially in substrate 534 relative to the Z-axis; fin-insulator 536 formed against fins 530 and 532; and a gate insulating layer 538 formed on fins 530 and 532, and on the upper surface of N-well 505, and fin-insulator 536 and substrate 534.

FIG. 5A further includes an MD structure 514(3). FIG. 5B further includes a gate segment 510(2). In each of FIGS. 5A-5B: fins 530 in N-well 505 represent a portion of an active region corresponding to active region 208P(1) of FIG. 2A; and fins 532 represent a portion of an active region corresponding to active region 208N(1) of FIG. 2A.

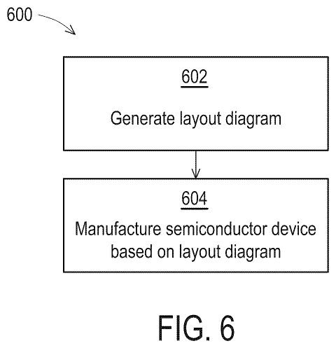

FIG. 6 is a flowchart (flow diagram) of a method 600 of manufacturing device, in accordance with some embodiments.

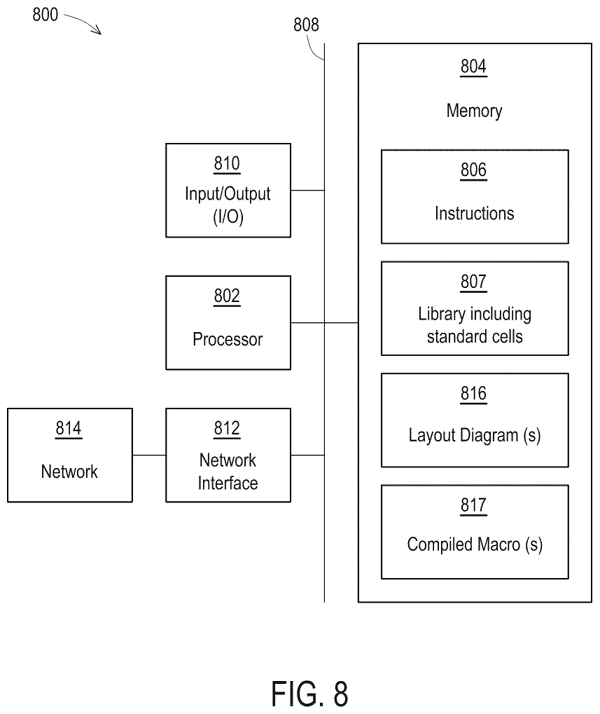

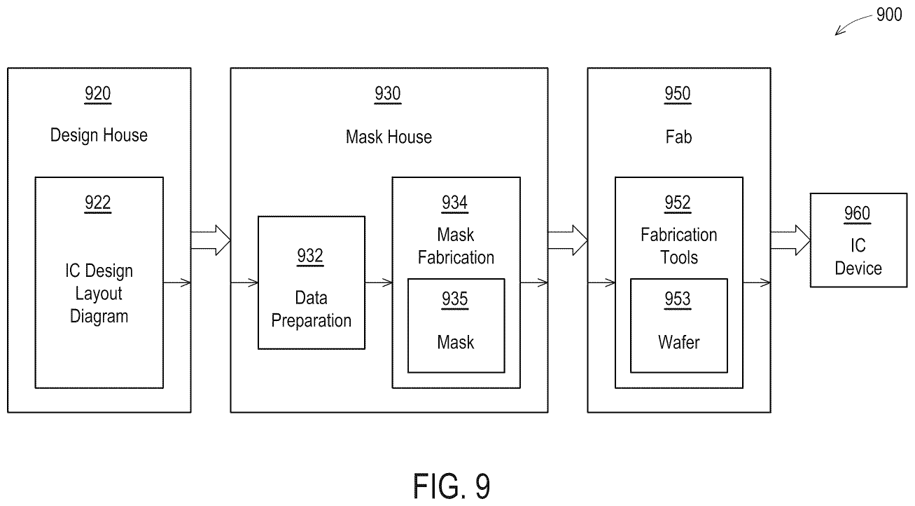

Method 600 is implementable, for example, using EDA system 800 (FIG. 8, discussed below) and an IC manufacturing system 900 (FIG. 9, discussed below), in accordance with some embodiments. Examples of cell regions and/or macro regions which can be manufactured according to method 600 include the cell regions and/or macro regions disclosed herein, or the like.

In FIG. 6, method 600 includes blocks 602-604. At block 602, a layout diagram is generated which, among other things, includes one or more layout diagrams corresponding to one or more of the cell regions herein, one or more of the macro regions disclosed herein, or the like. Block 602 is implementable, for example, using EDA system 800 (FIG. 8, discussed below), in accordance with some embodiments. From block 602, flow proceeds to block 604.

At block 604, based on the layout diagram, at least one of (A) one or more photolithographic exposures are made or (b) one or more photolithography masks are fabricated or (C) one or more components in a layer of a device, e.g., a device is fabricated. See discussion below of IC manufacturing system 900 in FIG. 9 below.

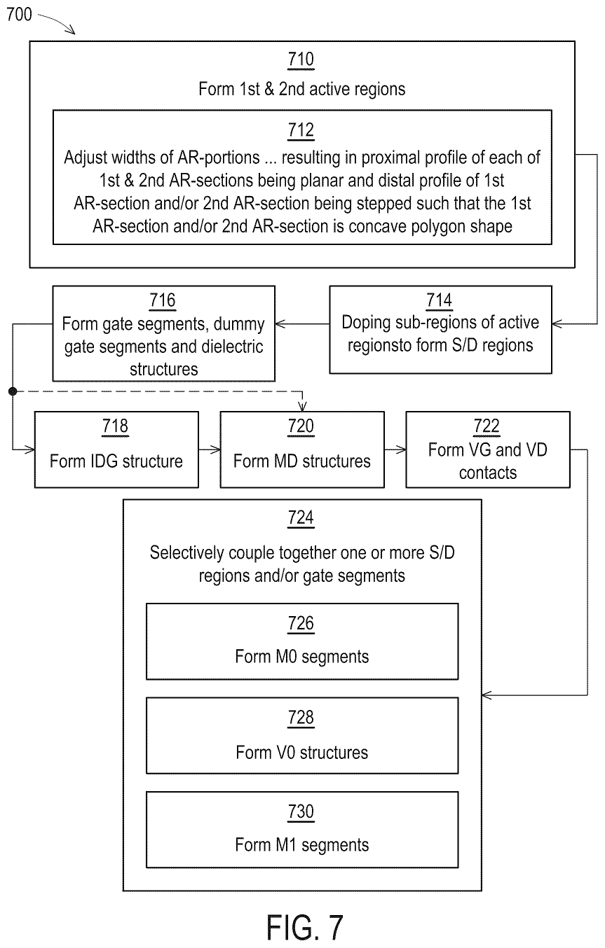

FIG. 7 is a flowchart of a method 700 of manufacturing a device, in accordance with some embodiments.

Method 700 is an example of block 604 (see FIG. 6, discussed above). Method 700 is implementable, for example, using IC manufacturing system 900 (see FIG. 9, discussed below), in accordance with some embodiments. Examples of a devices which can be manufactured according to method 700 include devices that include one or more of cell regions disclosed herein or one or more of the macro regions disclosed herein, or the like. Method 700 includes blocks 710-730.

At block 710, first (e.g., 208N(1) of FIG. 2A; or the like) and second (e.g., 208P(1) of FIG. 2A; or the like) active regions are formed extending in a first direction (e.g., parallel to the X-axis). The first active region has a first conductivity type (e.g., N-type in FIG. 2A or the like). The second active region has a second conductivity type (e.g., P-type in FIG. 2A; or the like) which is different than the first conductivity type. The first (e.g., 208N(1)) and second (e.g., 208P(1)) active regions are on opposite sides of a first reference line (e.g., 222(1)) extending parallel to the first direction (e.g., X-axis) and are adjacent relative to a second direction (e.g., parallel to the Y-axis) perpendicular to the first direction. Within block 710, flow proceeds to block 712.

At block 712, the widths of AR-portions of the first (e.g., 208N(1)) and second (e.g., 208P(1)) active regions are adjusted. Examples of the AR-portions include AR-portions 218N(1)-218N(2) and 218P(1)-218P(2) of FIG. 2A, or the like. Adjacent AR-portions of an active region define an AR-section. Examples of AR-sections include AR-sections 204N(1) and 204P(1) of FIG. 2A, or the like. The adjusting of AR-portion widths results in the following: the proximal profile of each of the first (e.g., 204N(1)) and second (e.g., 204P(1)) AR-sections being planar; and the distal profile of the first AR-section (e.g., 204N(1)) and/or second (e.g., 204P(1)) AR-section being stepped such that the first AR-section (e.g., 204N(1)) and/or second e.g., 204P(1)) AR-section is concave polygon shape. From block 712, flow exits block 710 and proceeds to block 714.

At block 714, sub-regions of the ARs are doped to form S/D regions. Examples of the S/D regions are discussed in the context of FIG. 2A. From block 714, flow proceeds to block 716.

At block 716, gate segments (e.g., 210(1)-210(2) of FIG. 2A, or the like), dummy gate segments (e.g., 212(1)-210(3) of FIG. 2A, or the like) and dielectric structures (e.g., 206(1)-206(4) of FIG. 2A, or the like) are formed which extend in the second direction (e.g., parallel to the Y-axis). From block 716, flow proceeds to block 718.

At block 718, the dummy gate segments (e.g., 212(1)-210(3) of FIG. 2A, or the like) are converted into IDG structures are formed. Discussion of IDG structures is included in the discussion of FIG. 2A. From block 718, flow proceeds to block 720. In some embodiments, the dummy gate segments are not converted to IDG structures; in such embodiments, flow proceeds from block 716 to block 720.

At block 720, MD structures (e.g., 214(1)-214(4) of FIG. 2A, or the like) are formed. From block 720, flow proceeds to block 722.

At block 722, VG contacts (not shown) and VD contacts (not shown) are formed over corresponding (A) ones of the gate segments (e.g., 210(1)-210(2) of FIG. 2A, or the like) and (B) ones of the MD structures (e.g., 214(1)-214(4) of FIG. 2A, or the like). From block 722, flow proceeds to block 724.

At block 724, one or more of the S/D regions and/or one or more of the gate segments are coupled together to form corresponding transistors. Within block 724, flow proceeds to block 726.

At block 726, M0 segments (not shown) are formed over (A) corresponding ones of the VG contacts and/or (B) corresponding ones of the VD contacts. From block 726, flow proceeds to block 728.

At block 736, a first M0 segment (e.g., 214(1)) is formed which overlies the third active region (e.g., 208P(2) of FIG. 2A; 208P(3), 208N(4) of FIG. 2D; or the like) and

At block 728, V0 structures (not shown) are formed over corresponding ones of the M0 segments. From block 728, flow proceeds to block 730.

At block 730, M1 segments (not shown) are formed over corresponding ones of the V0 structures.

In some embodiments, regarding block 716, results of forming gate segments include: the first gate segment (e.g., 210(2)) overlapping the first AR-portion (e.g., 218N(2)) of the first active region (e.g., 208N(1)) and the first AR-portion (e.g., 218P(2)) of the second active region (e.g., 208P(1)); and the second gate segment (e.g., 210(1)) overlapping a second AR-portion (e.g., 218N(1)) of the first active region (e.g., 208N(1)) and a second AR-portion (e.g., 218P(1)) of the second active region (e.g., 208P(1)). In some embodiments, block 716 includes, relative to the second direction (e.g., Y-axis), trimming a length of the first gate segment (e.g., 210(2)) to be different than a length of the second gate segment (e.g., 210(1)).

In some embodiments, method 700 further includes forming dielectric structures extending in the second direction (e.g., Y-axis) and including first (e.g., 206(3)), second (e.g., 206(4)), third (e.g., 206(1)) and fourth (e.g., 206(2)) dielectric structures. The first (e.g., 206(3)) and second (e.g., 206(4)) dielectric structures correspondingly abut first and second ends of the first gate segment (e.g., 210(2)). The third (e.g., 206(1)) and fourth (e.g., 206(2)) dielectric structures correspondingly abut first and second ends of the second gate segment (e.g., 210(1)). Relative to the second direction (e.g., Y-axis), the forming dielectric structures includes forming a length of each of the first (e.g., 206(3)) and second (e.g., 206(4)) dielectric structures to be different than a length of each of the third (e.g., 206(1)) and fourth (e.g., 206(2)) dielectric structures.

In some embodiments, block 716 includes forming first (e.g., 412(2)) and second (e.g., 412(1)) ones of the dummy gate segments to be free from having a non-dummy gate segment therebetween which results in first dummy-AR-portions (e.g., 424N(1), 424P(1)) of the first (e.g., 208N(1)) and second (e.g., 208P(1)) active regions being defined between the first (e.g., 412(2)) and second (e.g., 412(1)) dummy gate segments.

Regarding each of the first (e.g., 408N(1)) and second (e.g., 408P(1)) active regions, the first dummy-AR-portion (e.g., 424N(1), 424P(1)) is between and first-direction-adjacent (e.g., horizontally-adjacent) the following: a third one (e.g., 418N(11), 418P(11)) of the AR-portions; and the first (e.g., 418N(13), 418P(13)) or second (e.g., 418N(12), 418P(12)) AR-portions.

In some embodiments, regarding block 716, results of forming gate segments include:
each of the first (e.g., 210(2)) and second (e.g., 210(1)) gate segments overlapping the first active region (e.g., 208N(1)) and the second active region (e.g., 208P(1)). In some embodiments, block 716 includes, relative to the second direction (e.g., Y-axis), trimming each of the gate segments (e.g., 210(2)) to overhang the distal profiles by a substantially uniform overhang-distance.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a processor 802 (e.g., a hardware processor) and a non-transitory, computer-readable storage medium 804. Storage medium 804, amongst other things, is encoded with, i.e., stores, computer program code 806, i.e., a set of executable instructions. Execution of instructions 806 by processor 802 represents (at least in part) an EDA tool which implements a portion of or all, e.g., one or more methods of generating layout diagrams corresponding to the layout diagrams disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and storage medium 804 are capable of connecting to external elements via network 814. Processor 802 is configured to execute computer program code 806 encoded in storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, storage medium 804 is an electronic, magnetic, optical, electromagnetic, infrared, and/or a semiconductor system (or apparatus or device). For example, storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, storage medium 804 includes a compact disk-read only memory (CD-ROM), a compact disk-read/write (CD-R/W), and/or a digital video disc (DVD).

In one or more embodiments, storage medium 804 stores instructions, i.e., computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the layout diagrams disclosed herein. Storage medium 804 stores one or more layout diagrams 816 such as one or more layout diagrams corresponding to the layout diagrams disclosed herein, one or more compiled macros 817 based on layout diagrams including one or more of the layout diagrams disclosed herein, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 702 of FIG. 7, the IC manufacturing system 900 implements block 704 of FIG. 7 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 6, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a cell region (of a semiconductor device) includes: active regions extending in a first direction and including first and second active regions; the first and second active regions being on opposite sides of a first reference line extending parallel to the first direction, being adjacent relative to a second direction perpendicular to the first direction, and being configured correspondingly for a first type of dopant and a different second type of dopant; and dummy gate segments extending in the second direction, each of the dummy gate segments overlapping the active regions; corresponding AR-portions of the active regions being defined between first-direction-adjacent ones of the dummy gate segments; each of the first and second active regions including first-direction-adjacent first and second ones of the AR-portions; the first and second AR-portions defining first and second AR-sections; relative to the second direction, each of the first and second AR-sections having first and second profiles that correspondingly are proximal and distal to the first reference line; and the proximal profile of each of the first and second AR-sections being planar; and the distal profile of the first AR-section or the second AR-section being stepped such that the first AR-section or the second AR-section is a concave polygon shape.

In some embodiments, relative to the second direction, a width of the first AR-portion of the first active region is different than a width of the second AR-portion of the first active region.

In some embodiments, relative to the second direction, a width of the first AR-portion of the second active region is different than a width of the second AR-portion of the second active region.

In some embodiments, the cell region further includes: gate segments extending in the second direction and including first and second gate segments; the first gate segment overlaps the first AR-portion of the first active region and the first AR-portion of the second active region; the second gate segment overlaps a second AR-portion of the first active region and a second AR-portion of the second active region; and, relative to the second direction, a length of the first gate segment is different than a length of the second gate segment.

In some embodiments, the cell region further includes: dielectric structures extending in the second direction and including first, second, third and fourth dielectric structures; the first and second dielectric structures correspondingly abutting first and second ends of the first gate segment; the third and fourth dielectric structures correspondingly abutting first and second ends of the second gate segment; and, relative to the second direction, a length of each of the first and second dielectric structures is different than a length of each of the third and fourth dielectric structures.

In some embodiments, each of the first and second active regions further including a third AR-portion; the first and second AR-portions defining first and second AR-sections; the cell region further comprises a well configured with the second type of dopant; the first and second AR-portions are in a first region of the well; the third AR-portion is in a second region of the well; and, relative to the second direction, a width of the first region of the well is different than a width of the second region of the well.

In some embodiments, first and second ones of the dummy gate segments are free from having a non-dummy gate segment therebetween; first dummy-AR-portions of the first and second active regions are defined between the first and second dummy gate segments; regarding each of the first and second active regions, the first dummy-AR-portion is between and first-direction-adjacent a third one of the AR-portions and the first or second AR-portions.

In some embodiments, the distal profile of the first AR-section and the second AR-section is stepped such that each of the first AR-section and the second AR-section is a concave polygon shape.

In some embodiments, the cell region further includes: gate segments extending in the second direction and including first and second gate segments; each of the first and second gate segments overlapping the first active region and the second active region; and each of the gate segments overhanging the distal profiles by a substantially uniform overhang-distance.

In some embodiments, a cell region (of a semiconductor device) includes: active regions extending in a first direction and including first and second active regions; the first and second active regions being on opposite sides of a first reference line extending parallel to the first direction, being adjacent relative to a second direction perpendicular to the first direction, and being configured correspondingly for a first type of dopant and a different second type of dopant; and dummy gate segments extending in the second direction, each of the dummy gate segments overlapping the active regions; corresponding AR-portions of the active regions being defined between first-direction-adjacent ones of the dummy gate segments; each of the first and second active regions including first-direction-adjacent first and second ones of the AR-portions; the first and second AR-portions defining first and second AR-sections; relative to the second direction, each of the first and second AR-sections having first and second profiles that correspondingly are proximal and distal to the first reference line; and the distal profile of the first AR-section or the second AR-section being stepped such that the first AR-section or the second AR-section is a concave polygon shape; gate segments extending in the second direction and including first and second gate segments; each of the first and second gate segments overlapping the first active region and the second active region; each of the first and second gate segments overhanging the distal profiles by a substantially uniform overhang-distance.

In some embodiments, the distal profile of the first AR-section and the second AR-section being stepped such that the first AR-section or the second AR-section is a concave polygon shape.

In some embodiments, relative to the second direction, a length of the first gate segment is different than a length of the second gate segment.

In some embodiments, the cell region further includes: dielectric structures extending in the second direction and including first, second, third and fourth dielectric structures; the first and second dielectric structures correspondingly abutting first and second ends of the first gate segment; the third and fourth dielectric structures correspondingly abutting first and second ends of the second gate segment; and, relative to the second direction, a length of at least one of the first to fourth dielectric structures is different than other ones of the first to fourth dielectric structures.

In some embodiments, a method (of forming a cell region of a semiconductor device) includes: forming active regions extending in a first direction and including first and second active regions, the first and second active regions being on opposite sides of a first reference line extending parallel to the first direction, being adjacent relative to a second direction perpendicular to the first direction, and being configured correspondingly for a first type of dopant and a different second type of dopant; and forming dummy gate segments extending in the second direction, each of the dummy gate segments overlapping the active regions; and wherein: corresponding AR-portions of the active regions being defined between first-direction-adjacent ones of the dummy gate segments; each of the first and second active regions including first-direction-adjacent first and second ones of the AR-portions; the first and second AR-portions defining first and second AR-sections, relative to the second direction, each of the first and second AR-sections having first and second profiles that correspondingly are proximal and distal to the first reference line; and the forming active regions including as follows, adjusting widths of the AR-portions with results including as follows, the proximal profile of each of the first and second AR-sections being planar, and the distal profile of the first AR-section or the second AR-section being stepped such that the first AR-section or the second AR-section is a concave polygon shape.

In some embodiments, the forming active regions further includes as follows, relative to the second direction, forming a width of the first AR-portion of the first active region to be different than a width of the second AR-portion of the first active region.

In some embodiments, the method further includes: forming gate segments extending in the second direction and including first and second gate segments, the first gate segment overlapping the first AR-portion of the first active region and the first AR-portion of the second active region, and the second gate segment overlapping a second AR-portion of the first active region and a second AR-portion of the second active region; and, relative to the second direction, the forming gate segments including as follows, trimming a length of the first gate segment to be different than a length of the second gate segment.

In some embodiments, the method further includes: forming dielectric structures extending in the second direction and including first, second, third and fourth dielectric structures, the first and second dielectric structures correspondingly abutting first and second ends of the first gate segment, and the third and fourth dielectric structures correspondingly abutting first and second ends of the second gate segment; and, relative to the second direction, the forming dielectric structures including as follows, forming a length of each of the first and second dielectric structures to be different than a length of each of the third and fourth dielectric structures.

In some embodiments, the forming dummy gate segments includes as follows, forming first and second ones of the dummy gate segments to be free from having a non-dummy gate segment therebetween, first dummy-AR-portions of the first and second active regions being defined between the first and second dummy gate segments; regarding each of the first and second active regions, the first dummy-AR-portion is between and first-direction-adjacent a third of the AR-portions and the first or second AR-portions.

In some embodiments, the adjusting widths has further results including as follows, the distal profile of the first AR-section and the second AR-section being stepped such that each of the first AR-section and the second AR-section is a concave polygon shape.

In some embodiments, the method further includes: forming gate segments extending in the second direction and including first and second gate segments; each of the first and second gate segments overlapping the first active region and the second active region; and, relative to the second direction, the forming gate segments including as follows, trimming each of the gate segments to overhang the distal profiles by a substantially uniform overhang-distance.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A cell region of a device, the cell region comprising:
active regions extending in a first direction and including first and second active regions;
the first and second active regions being on opposite sides of a first reference line extending parallel to the first direction, being adjacent relative to a second direction perpendicular to the first direction, and being configured correspondingly for a first type of dopant and a different second type of dopant; and
dummy gate segments extending in the second direction, each of the dummy gate segments overlapping the active regions;
corresponding AR-portions of the active regions being defined between first-direction-adjacent ones of the dummy gate segments;
each of the first and second active regions including first-direction-adjacent first and second ones of the AR-portions;
the first and second AR-portions defining first and second AR-sections;
relative to the second direction, each of the first and second AR-sections having first and second profiles that correspondingly are proximal and distal to the first reference line; and
the proximal profile of each of the first and second AR-sections being planar; and
the distal profile of the first AR-section or the second AR-section being stepped such that the first AR-section or the second AR-section is a concave polygon shape.

2. The cell region of claim 1, wherein:
relative to the second direction,
a width of the first AR-portion of the first active region is different than a width of the second AR-portion of the first active region.

3. The cell region of claim 2, wherein:
relative to the second direction,
a width of the first AR-portion of the second active region is different than a width of the second AR-portion of the second active region.

4. The cell region of claim 2, further comprising:
gate segments extending in the second direction and including first and second gate segments;
the first gate segment overlaps the first AR-portion of the first active region and the first AR-portion of the second active region;
the second gate segment overlaps a second AR-portion of the first active region and a second AR-portion of the second active region; and
relative to the second direction,
a length of the first gate segment is different than a length of the second gate segment.

5. The cell region of claim 4, further comprising:
dielectric structures extending in the second direction and including first, second, third and fourth dielectric structures;
the first and second dielectric structures correspondingly abutting first and second ends of the first gate segment;
the third and fourth dielectric structures correspondingly abutting first and second ends of the second gate segment; and
relative to the second direction,
a length of each of the first and second dielectric structures is different than a length of each of the third and fourth dielectric structures.

6. The cell region of claim 1, wherein:
each of the first and second active regions further including a third AR-portion;
the first and second AR-portions defining first and second AR-sections;
the cell region further comprises a well configured with the second type of dopant;
the first and second AR-portions are in a first region of the well;
the third AR-portion is in a second region of the well; and
relative to the second direction,
a width of the first region of the well is different than a width of the second region of the well.

7. The cell region of claim 1, wherein:
first and second ones of the dummy gate segments are free from having a non-dummy gate segment therebetween;
first dummy-AR-portions of the first and second active regions are defined between the first and second dummy gate segments;
regarding each of the first and second active regions,
the first dummy-AR-portion is between and first-direction-adjacent a third one of the AR-portions and the first or second AR-portions.

8. The cell region of claim 1, wherein:
the distal profile of the first AR-section and the second AR-section is stepped such that each of the first AR-section and the second AR-section is a concave polygon shape.

9. The cell region of claim 1, further comprising
gate segments extending in the second direction and including first and second gate segments;
each of the first and second gate segments overlapping the first active region and the second active region; and
each of the gate segments overhanging the distal profiles by a substantially uniform overhang-distance.

10. A cell region of a device, the cell region comprising:
active regions extending in a first direction and including first and second active regions;
the first and second active regions being on opposite sides of a first reference line extending parallel to the first direction, being adjacent relative to a second direction perpendicular to the first direction, and being configured correspondingly for a first type of dopant and a different second type of dopant; and
dummy gate segments extending in the second direction, each of the dummy gate segments overlapping the active regions;
corresponding AR-portions of the active regions being defined between first-direction-adjacent ones of the dummy gate segments;
each of the first and second active regions including first-direction-adjacent first and second ones of the AR-portions;
the first and second AR-portions defining first and second AR-sections;
relative to the second direction, each of the first and second AR-sections having first and second profiles that correspondingly are proximal and distal to the first reference line; and
the distal profile of the first AR-section or the second AR-section being stepped such that the first AR-section or the second AR-section is a concave polygon shape;
gate segments extending in the second direction and including first and second gate segments;
each of the first and second gate segments overlapping the first active region and the second active region;
each of the first and second gate segments overhanging the distal profiles by a substantially uniform overhang-distance.

11. The cell region of claim 10, wherein:
the distal profile of the first AR-section and the second AR-section being stepped such that the first AR-section or the second AR-section is a concave polygon shape.

12. The cell region of claim 10, wherein:
relative to the second direction,
a length of the first gate segment is different than a length of the second gate segment.

13. The cell region of claim 12, further comprising:
dielectric structures extending in the second direction and including first, second, third and fourth dielectric structures;
the first and second dielectric structures correspondingly abutting first and second ends of the first gate segment;
the third and fourth dielectric structures correspondingly abutting first and second ends of the second gate segment; and
relative to the second direction,
a length of at least one of the first to fourth dielectric structures is different than other ones of the first to fourth dielectric structures.

14. A method of manufacturing cell region of a device, the method comprising:
forming active regions extending in a first direction and including first and second active regions,
the first and second active regions being on opposite sides of a first reference line extending parallel to the first direction, being adjacent relative to a second direction perpendicular to the first direction, and being configured correspondingly for a first type of dopant and a different second type of dopant; and
forming dummy gate segments extending in the second direction, each of the dummy gate segments overlapping the active regions; and
wherein:
corresponding AR-portions of the active regions being defined between first-direction-adjacent ones of the dummy gate segments;
each of the first and second active regions including first-direction-adjacent first and second ones of the AR-portions;
the first and second AR-portions defining first and second AR-sections,
relative to the second direction, each of the first and second AR-sections having first and second profiles that correspondingly are proximal and distal to the first reference line; and
the forming active regions including as follows,
adjusting widths of the AR-portions with results including as follows,
the proximal profile of each of the first and second AR-sections being planar, and
the distal profile of the first AR-section or the second AR-section being stepped such that the first AR-section or the second AR-section is a concave polygon shape.

15. The method of claim 14, wherein:
the forming active regions further includes as follows,
relative to the second direction,
forming a width of the first AR-portion of the first active region to be different than a width of the second AR-portion of the first active region.

16. The method of claim 15, further comprising:
forming gate segments extending in the second direction and including first and second gate segments,
the first gate segment overlapping the first AR-portion of the first active region and the first AR-portion of the second active region, and
the second gate segment overlapping a second AR-portion of the first active region and a second AR-portion of the second active region; and
relative to the second direction, the forming gate segments including as follows,
trimming a length of the first gate segment to be different than a length of the second gate segment.

17. The method of claim 16, further comprising:
forming dielectric structures extending in the second direction and including first, second, third and fourth dielectric structures,
the first and second dielectric structures correspondingly abutting first and second ends of the first gate segment, and
the third and fourth dielectric structures correspondingly abutting first and second ends of the second gate segment; and
relative to the second direction, the forming dielectric structures including as follows,
forming a length of each of the first and second dielectric structures to be different than a length of each of the third and fourth dielectric structures.

18. The method of claim 14, wherein:
the forming dummy gate segments includes as follows,
forming first and second ones of the dummy gate segments to be free from having a non-dummy gate segment therebetween,
first dummy-AR-portions of the first and second active regions being defined between the first and second dummy gate segments;
regarding each of the first and second active regions,
the first dummy-AR-portion is between and first-direction-adjacent a third of the AR-portions and the first or second AR-portions.

19. The method of claim 14, wherein:
the adjusting widths has further results including as follows,
the distal profile of the first AR-section and the second AR-section being stepped such that each of the first AR-section and the second AR-section is a concave polygon shape.

20. The method of claim 14, further comprising
forming gate segments extending in the second direction and including first and second gate segments;
each of the first and second gate segments overlapping the first active region and the second active region; and
relative to the second direction, the forming gate segments including as follows,
trimming each of the gate segments to overhang the distal profiles by a substantially uniform overhang-distance.
